(19) United States
(12) Patent Application Publication
(10) Pub. No.: US 2016/0246125 A1
(43) Pub. Date: Aug. 25, 2016

(54) ARRAY SUBSTRATE AND DISPLAY DEVICE

(71) Applicant: Shenzhen China Star Optoelectronics Technology Co., Ltd., Shenzhen, Guangdong (CN)

(72) Inventor: Zui Wang, Shenzhen, Guangdong (CN)

(73) Assignee: Shenzhen China Star Optoelectronics Technology Co., Ltd., Shenzhen, Guangdong (CN)

(21) Appl. No.: 14/418,179

(22) PCT Filed: Jan. 13, 2015
(86) PCT No.: PCT/CN2015/070567

§ 371 Date: May 9, 2016

(30) Foreign Application Priority Data
Dec. 10, 2014 (CN) 201410752841.8

(51) Int. Cl. G02F 1/1343; H01L 27/12; G02F 1/1333; G02F 1/1362; G02F 1/1335; G02F 1/1368

(52) U.S. Cl. CPC G02F 1/134309; G02F 1/133514; G02F 1/1368; G02F 1/133345; G02F 1/136286; G02F 1/13624; G02F 1/13439; H01L 27/124

(57) ABSTRACT

An array substrate and a display device, which can solve the technical problem of short circuit of transparent electrode and the failure of detection thereof, are provided. In the array substrate, each pixel unit comprises a primary pixel electrode, a secondary pixel electrode, and a voltage dividing capacitor. The voltage dividing capacitor comprises a common terminal electrode and a voltage dividing terminal electrode. The primary pixel electrode, the secondary pixel electrode, and the common terminal electrode are located at the same layer.

The present application claims benefit of Chinese patent application CN 201410752841.8, entitled “An Array Substrate and A Display Device” and filed on Dec. 10, 2014, the entirety of which is incorporated herein by reference.

### TECHNICAL FIELD

The present disclosure relates to the technical field of display, and in particular to an array substrate and a display device.

### TECHNICAL BACKGROUND

As display technology develops, liquid crystal display devices have become the most popular display devices.

A vertical alignment (VA) liquid crystal display device is a common liquid crystal display device. At present, in order to eliminate the phenomenon of color cast with large viewing angle of a VA liquid crystal display device, each pixel unit is divided into a primary pixel region and a secondary pixel region, and further provided with a voltage dividing capacitor therein. As shown in FIG. 1, a primary pixel electrode 10 is disposed in the primary pixel region, a secondary pixel electrode 20 is disposed in the secondary pixel region, and the voltage dividing capacitor is formed by an overlap between a part of a common electrode line 30 and a voltage dividing electrode 40.

During display, the primary pixel electrode 10 and the secondary pixel electrode 20 are charged with the same potential first. Subsequently, a voltage of the secondary pixel electrode 20 is divided by the voltage dividing capacitor, so that the potential of the secondary pixel electrode 20 is lower than that of the primary pixel electrode 10. In this case, the brightness of the secondary pixel region is slightly lower than that of the primary pixel region. In the meantime, the angle of deflection of the liquid crystal molecules in the primary pixel region is different from that of the liquid crystal molecules in the secondary pixel region, whereby the phenomenon of color cast with large viewing angle of the VA liquid crystal display can be alleviated.

In the prior art, the voltage dividing electrode 40, the primary pixel electrode 10, and the secondary pixel electrode 20 are all disposed in a transparent electrode layer. During the manufacturing of liquid crystal display devices, the problem of remnant of transparent electrode would often occur. As a result, the voltage dividing electrode 40 and the primary pixel electrode 10 (or secondary pixel electrode 20) would short out, causing the voltage dividing capacitor in this pixel unit to fail. Consequently, the brightness of the secondary pixel region is always the same as the primary pixel region, resulting in undesirable phenomenon, such as bright spots on the pixel unit.

According to an existing detection method, all the scan lines are turned on simultaneously to charge all the pixel units, so that the brightness of the primary pixel region of each pixel unit is the same as that of the secondary pixel region thereof. In this case, short circuit of transparent electrode would not be able to be detected. Therefore, in the prior art, the problem of short circuit of transparent electrode can neither be detected timely, nor eliminated promptly.

### SUMMARY OF THE INVENTION

The present disclosure aims to provide an array substrate and a display device, so that the technical problem of short circuit of transparent electrode can be eliminated promptly.

An array substrate is provided according to the present disclosure, comprising a plurality of pixel units, each having a primary pixel region, a secondary pixel region, and a dividing capacitor, wherein a primary pixel electrode is disposed in the primary pixel region, a secondary pixel electrode is disposed in the secondary pixel region, and the dividing capacitor consists of a common terminal electrode and a voltage dividing terminal electrode; and the primary pixel electrode, the secondary pixel electrode, and the common terminal electrode are located at a same layer.

Further, an insulation layer is disposed between the common terminal electrode and the voltage dividing terminal electrode.

Preferably, a drive scan line, a dividing scan line, and a data line are arranged in each pixel unit, and the voltage dividing terminal electrode and the data line are located at the same layer.

Further, each of the pixel units comprises a first switching element, a second switching element, and a third switching element, wherein the first switching element is connected to the drive scan line with a gate thereof, to the data line with a source thereof, and to the primary pixel electrode with a drain thereof; the second switching element is connected to the drive scan line with a gate thereof, to the data line with a source thereof, and to the secondary pixel electrode with a drain thereof; and the third switching element is connected to the dividing scan line with a gate thereof, to the secondary pixel electrode with a source thereof, and to the voltage dividing terminal electrode with a drain thereof.

Preferably, the drain of the third switching element and the voltage dividing terminal electrode are structured as one-piece.

Preferably, the common terminal electrodes of pixel units in a same line are connected with each other to form an integral common terminal electrode line.

Preferably, the common terminal electrode line is connected with a common voltage bus at a marginal region of the array substrate.

Further, the common electrode lines are connected with one another through connecting lines.

The present disclosure further provides a display device, comprising a color filter substrate and the array substrate.

Further, the display device is a vertical alignment display device.

The present disclosure has the following beneficial effects. In the array substrate according to the present disclosure, the primary pixel electrode, secondary pixel electrode, and the common terminal electrode of the voltage dividing capacitor of the pixel unit are located at the same patterning layer. If remnant of transparent electrode occurs, the common terminal electrode and the primary pixel electrode (or secondary pixel electrode) would short out. In this case, the potential on the primary pixel electrode (or secondary pixel electrode) is always the same with the common voltage, causing dark spots to be presented on the pixel unit.

When the display device is detected through the existing detection method, dark spots would still occur to the pixel unit. However, the dark spots can be detected easily, and thus the problem of short circuit of the transparent electrode can be determined and eliminated timely. Therefore, the yield of the product can be improved.

Other features and advantages of the present disclosure will be further explained in the following description and partially become self-evident therefrom, or be understood through the embodiments of the present disclosure. The objectives and advantages of the present disclosure will be achieved through the structure specifically pointed out in the description, claims, and the accompanying drawings.

### BRIEF DESCRIPTION OF THE ACCOMPANYING DRAWINGS

In order to clarify the technical solutions of the embodiments of the present disclosure, the drawings relating to the embodiments will be explained briefly. In which:

FIG. 1 schematically shows a pixel unit in an array substrate in the prior art,

FIG. 2 schematically shows a pixel unit in an array substrate according to an example of the present disclosure,

FIG. 3 shows a circuit diagram of the pixel unit in the array substrate according to an example of the present disclosure,

FIG. 4 schematically shows the array substrate according to an example of the present disclosure, and

FIG. 5 schematically shows an array substrate according to another example of the present disclosure.

### DETAILED DESCRIPTION OF THE EMBODIMENTS

The present disclosure will be explained in details with reference to the embodiments and the accompanying drawings, whereby it can be fully understood how to solve the technical problem by the technical means according to the present disclosure and achieve the technical effects thereof, and thus the technical solution according to the present disclosure can be implemented. It is important to note that as long as there is no structural conflict, all the technical features mentioned in all the embodiments may be combined together in any manner, and the technical solutions obtained in this manner all fall within the scope of the present disclosure.

The present disclosure provides an array substrate which can be used in a vertical alignment liquid crystal display device. The array substrate comprises a plurality of pixel units, each having a primary pixel region, a secondary pixel region, and a voltage dividing capacitor.

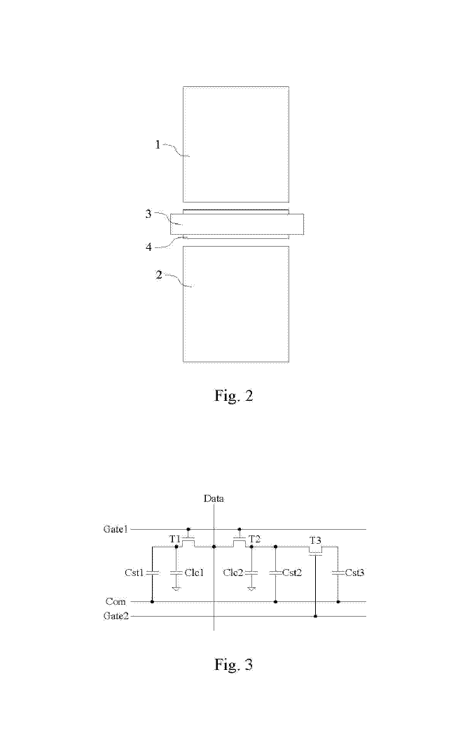

As shown in FIG. 2, a primary pixel electrode 1 is disposed in the primary pixel region, and a secondary pixel electrode 2 is disposed in the secondary pixel region. The dividing capacitor comprises a common terminal electrode 3 and a voltage dividing terminal electrode 4. An insulation layer (not shown) is disposed between the common terminal electrode 3 and the voltage dividing terminal electrode 4. The primary pixel electrode 1, the secondary pixel electrode 2, and the common terminal electrode 3 are located at a same layer, i.e., a transparent electrode layer.

As shown in FIG. 3, in an example according to the present disclosure, a drive scan line Gate1, a dividing scan line Gate2, a data line Data, and a common electrode line Com are arranged in each pixel unit. Each of the pixel units further comprises a first switching element T1, a second switching element T2, and a third switching element T3. T1, T2, and T3 are preferably thin film transistors (TFT).

A gate of T1 is connected with Gate1, a source thereof is connected with Data, and a drain thereof is connected with the primary pixel electrode 1. In the primary pixel region, a primary storage capacitor Cst1 is formed between the primary pixel electrode 1 and Com, and a primary liquid crystal capacitor Clc1 is formed between the primary pixel electrode 1 and a common electrode on a color filter substrate.

A gate of T2 is connected with Gate1, s source thereof is connected with Data, and a drain thereof is connected with the secondary pixel electrode 2. In the secondary pixel region, a secondary storage capacitor Cst2 is formed between the secondary pixel electrode 2 and Com, and a secondary liquid crystal capacitor Clc2 is formed between the secondary pixel electrode 2 and the common electrode on the color filter substrate.

A gate of T3 is connected with Gate2, a source thereof is connected with the secondary pixel electrode 2, and a drain thereof is connected with the voltage dividing terminal electrode 4. A voltage dividing capacitor Cst3 is formed between the common terminal electrode 3 (having same potential as Com) and the voltage dividing terminal electrode 4.

In the course of displaying, at first, Gate1 is turned on and Gate2 is turned off, so that T1 and T2 are on and T3 is off. In the meantime, the primary pixel electrode 1 and the secondary pixel electrode 2 are charged by the data line respectively through T1 and T2, so that the primary pixel electrode 1 and the secondary pixel electrode 2 have the same potential, and Clc1, Cst1, Clc2 and Cst2 have the same voltage. Then, Gate1 is turned off, Gate2 is turned on, so that T1 and T2 are off and T3 is on. In this case, Cst3 will divide a part of a voltage of the secondary pixel electrode 2 through T3, so that the potential of the secondary pixel electrode 2 is reduced, whereby the voltage of Clc2 and that of Cst2 are both lowered while the voltages of Clc1 and Cst1 remain the same. At this time, the voltage of Clc2 is lower than that of Clc1, causing the brightness of the secondary pixel region to be slightly lower than that of the primary pixel region, and the angle of deflection of liquid crystal molecules in the primary pixel region to be different from that in the secondary pixel region. As a result, color cast with large viewing angle of the VA liquid crystal display device can be alleviated.

In the array substrate according to the present disclosure, the primary pixel electrode 1, secondary pixel electrode 2, and the common terminal electrode 3 of the voltage dividing capacitor Cst3 are located at the same layer. If remnant of transparent electrode occurs, the common terminal electrode 3 and the primary pixel electrode 1 (or secondary pixel electrode 2) would short out. In this case, the potential of the primary pixel electrode 1 (or secondary pixel electrode 2) is always the same with the common voltage, causing dark spots to be presented on the pixel unit.

When the display device is detected through an existing detection method, dark spots would still occur to the pixel unit. However, the dark spots can be detected easily, and thus the problem of short circuit of the transparent electrode can be determined and eliminated timely. Therefore, the yield of the product can be improved.

In an example according to the present disclosure, the voltage dividing electrode and the data line are located at the same layer, and thus they can be formed simultaneously in the same patterning process. Because the sources and drains of T1, T2, and T3 are also disposed in the same layer as the data line, as a preferred solution, the drain of T3 and the voltage dividing electrode can be structured as one-piece.

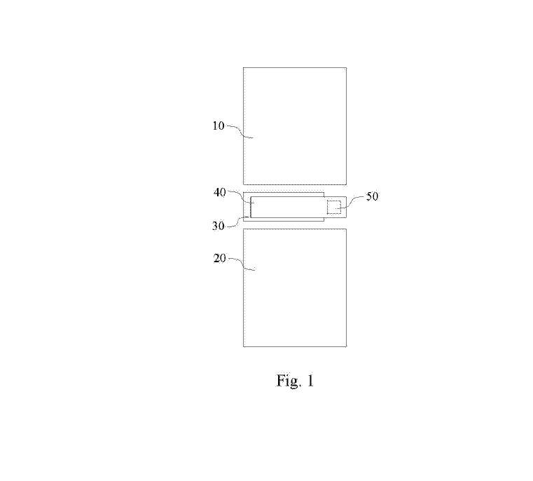

In the prior art, as shown in FIG. 1, because the voltage dividing capacitor is formed by an overlap between a part of a common electrode line 30 and a voltage dividing electrode 40, the voltage dividing electrode 40 should be connected with the drain of T3 through a via hole 50.

As compared with the prior art, it is unnecessary to provide via holes for the voltage dividing capacitor in the present disclosure. Thus, the number of via holes in the pixel unit can be reduced, whereby the aperture ratio of the pixel unit can be improved.

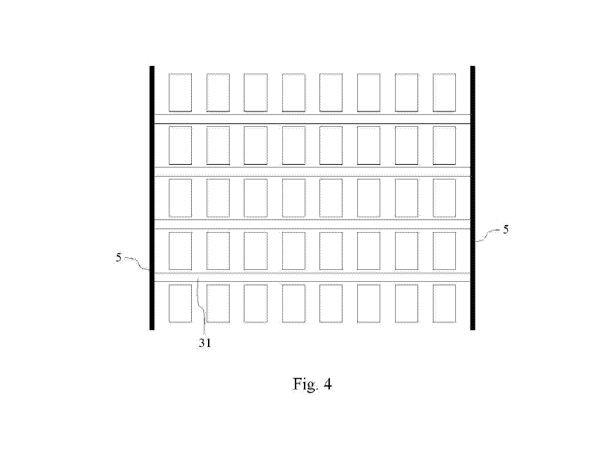

As shown in FIG. 4, in an example according to the present disclosure, the common terminal electrodes of pixel units in a same line are connected with each other and thus form an integral common terminal electrode line 31, so that the potential of the common terminal electrodes of the pixel units in each line can be more uniform and more stable. Further, the common terminal electrode line 31 can be connected with a common voltage bus 5 at a marginal region of the array substrate, whereby the input of common voltage to the common terminal electrode line 31 can be facilitated.

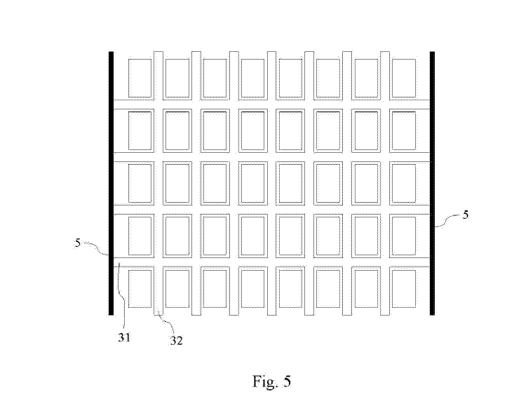

FIG. 5 shows another embodiment of an array substrate according to the present disclosure. On the basis that the common terminal electrodes of pixel units in a same line are connected with each other to form an integral common terminal electrode line 31, the common electrode lines 31 are connected with one another through longitudinal connecting lines 32. The connecting lines 32 can be formed right above the data lines. The common terminal electrodes of all the pixel units on the array substrate are connected with one another and form a net structure through the connecting lines 32, so that the potential of the common terminal electrodes of all the pixel units can be more uniform and more stable.

The present disclosure further provides a display device, which is preferably a VA display device. Specifically, the display device can be a liquid crystal television, a liquid crystal display device, a cell phone, a tablet PC, and the like. The display device comprises a color filter substrate and the array substrate according to the present disclosure.

The display device according to the present disclosure has the same technical feature as the array substrate according to the above example, and thus can solve the same technical problem and achieve the same technical effects.

The above embodiments are described only for better understanding, rather than restricting, the present disclosure. Any person skilled in the art can make amendments to the implementing forms or details without departing from the spirit and scope of the present disclosure. The scope of the present disclosure should still be subjected to the scope defined in the claims.

1. An array substrate comprising a plurality of pixel units, each having a primary pixel region, a secondary pixel region, and a dividing capacitor, wherein
a primary pixel electrode is disposed in the primary pixel region, a secondary pixel electrode is disposed in the secondary pixel region, and the dividing capacitor comprises a common terminal electrode and a voltage dividing terminal electrode, and
the primary pixel electrode, the secondary pixel electrode, and the common terminal electrode are located at a same layer.

2. The array substrate according to claim 1, wherein an insulation layer is disposed between the common terminal electrode and the voltage dividing terminal electrode.

3. The array substrate according to claim 1, wherein a drive scan line, a dividing scan line, and a data line are arranged in each pixel unit, and
the voltage dividing terminal electrode and the data line are located at the same layer.

4. The array substrate according to claim 3, wherein each of the pixel units comprises a first switching element, a second switching element, and a third switching element,
wherein the first switching element is connected to the drive scan line with a gate thereof, to the data line with a source thereof, and to the primary pixel electrode with a drain thereof,
the second switching element is connected to the drive scan line with a gate thereof, to the data line with a source thereof, and to the secondary pixel electrode with a drain thereof, and
the third switching element is connected to the dividing scan line with a gate thereof, to the secondary pixel electrode with a source thereof, and to the voltage dividing terminal electrode with a drain thereof.

5. The array substrate according to claim 4, wherein the drain of the third switching element and the voltage dividing terminal electrode are structured as one-piece.

6. The array substrate according to claim 1, wherein the common terminal electrodes of pixel units in a same line are connected with each other to form an integral common terminal electrode line.

7. The array substrate according to claim 6, wherein the common terminal electrode line is connected with a common voltage bus at a marginal region of the array substrate.

8. The array substrate according to claim 6, wherein the common electrode lines are connected with one another through connecting lines.

9. A display device, comprising a color filter substrate and an array substrate, wherein
the array substrate comprises a plurality of pixel units, each having a primary pixel region, a secondary pixel region, and a dividing capacitor, wherein
a primary pixel electrode is disposed in the primary pixel region, a secondary pixel electrode is disposed in the secondary pixel region, and the dividing capacitor comprises a common terminal electrode and a voltage dividing terminal electrode, and
the primary pixel electrode, the secondary pixel electrode, and the common terminal electrode are located at a same layer.

10. The display device according to claim 9, wherein an insulation layer is disposed between the common terminal electrode and the voltage dividing terminal electrode.

11. The display device according to claim 9, wherein a drive scan line, a dividing scan line, and a data line are arranged in each pixel unit, and
the voltage dividing terminal electrode and the data line are located at the same layer.

12. The display device according to claim 11, wherein each of the pixel units comprises a first switching element, a second switching element, and a third switching element,
wherein the first switching element is connected to the drive scan line with a gate thereof, to the data line with a source thereof, and to the primary pixel electrode with a drain thereof,
the second switching element is connected to the drive scan line with a gate thereof, to the data line with a source thereof, and to the secondary pixel electrode with a drain thereof, and
the third switching element is connected to the dividing scan line with a gate thereof, to the secondary pixel electrode with a source thereof, and to the voltage dividing terminal electrode with a drain thereof.

13. The display device according to claim 12, wherein the drain of the third switching element and the voltage dividing terminal electrode are structured as one-piece.

14. The display device according to claim 9, wherein the common terminal electrodes of pixel units in a same line are connected with each other to form an integral common terminal electrode line.

15. The display device according to claim 14, wherein the common terminal electrode line is connected with a common voltage bus at a marginal region of the array substrate.

16. The display device according to claim 14, wherein the common electrode lines are connected with each other through connecting lines.

17. The display device according to claim 9, wherein the display device is a vertical alignment display device.
